(19) United States
(12) Patent Application Publication
(10) Pub. No.: US 2026/0346397 A1
(43) Pub. Date: Nov. 5, 2026

(54) POLISHING COMPOSITION AND POLISHING METHOD USING THE SAME

(71) Applicant: FUJIMI INCORPORATED, Kiyosu-shi, Aichi (JP)

(72) Inventor: Ryo WAKABAYASHI, Kiyosu-shi, Aichi (JP)

(73) Assignee: FUJIMI INCORPORATED, Kiyosu-shi, Aichi (JP)

(21) Appl. No.: 19/484,948

(22) PCT Filed: May 14, 2024
(86) PCT No.: PCT/JP2024/017735

§ 371 Date: Nov. 17, 2025

(30) Foreign Application Priority Data
May 19, 2023 (JP) 2023-083318
Jun. 23, 2023 (JP) 2023-103624

(51) Int. Cl. B24B 37/04; C09G 1/02; H10P 52/40

(52) U.S. Cl. CPC B24B 37/04; C09G 1/02; H10P 52/403; H10P 52/409

(57) ABSTRACT

To provide means for allowing the polishing removal rate of a metallic material relative to the polishing removal rate of a resin material to be adjusted while maintaining a high polishing removal rate during polishing of an object to be polished containing a resin material and a metallic material.

Disclosed is a polishing composition to be used for polishing an object to be polished containing a resin material and a metallic material, the polishing composition containing abrasives, a first amine compound having 0 or 1 amino group, a second amine compound having 2 or more amino groups, and a dispersion medium.

### TECHNICAL FIELD

The present invention relates to a polishing composition and a polishing method using the same.

### BACKGROUND ART

In the semiconductor industry, a planarization technique is usually used to enhance the flatness of the surface of a semiconductor substrate (e.g., a wafer). Chemical mechanical polishing (CMP) is one of planarization techniques commonly used. Chemical mechanical polishing is a method for flattening the surface of an object to be polished (workpiece), such as a semiconductor substrate, by use of a polishing composition containing abrasives such as silica, alumina, or ceria, an anticorrosive, a surfactant, etc.

Further, a substrate containing a resin material (herein sometimes abbreviated as “resin-containing substrate”) is becoming popular. Therefore, needs for a polishing composition used to polish a resin-containing substrate are gradually increasing.

Japanese Patent Laid-Open No. 2005-268666 (U.S. Patent Application Publication No. 2005/0204638) discloses a chemical mechanical polishing composition containing alumina, a complexing agent, and an oxidizing agent. The chemical mechanical polishing composition disclosed in Japanese Patent Laid-Open No. 2005-268666 (U.S. Patent Application Publication No. 2005/0204638) can be used to perform chemical mechanical polishing on a resin layer and a conductor layer containing a metal.

### SUMMARY OF INVENTION

### Technical Problem

However, there has heretofore been no polishing composition capable of adjusting the polishing removal rate of a metallic material relative to the polishing removal rate of a resin material while polishing a substrate containing a resin material and a metallic material at high polishing removal rate.

It is therefore an object of the present invention to provide means for allowing the polishing removal rate of a metallic material relative to the polishing removal rate of a resin material to be adjusted while keeping a high polishing removal rate during polishing of an object to be polished containing a resin material and a metallic material.

### Solution to Problem

In order to achieve the above object, the present inventor has intensively studied. As a result, the present inventor has found that the above object can be achieved by using two or more specific amine compounds in combination, and this finding has led to the completion of the present invention.

Specifically, the above object of the present invention can be achieved by the following means (first polishing composition).

An aspect that can achieve the above object of the present invention is a polishing composition to be used to polish an object to be polished containing a resin material and a metallic material, the polishing composition containing abrasives, a first amine compound having 0 or 1 amino group (—NH₂), a second amine compound having two or more amino groups (—NH₂), and a dispersion medium.

The above object of the present invention can be achieved also by the following means (second polishing composition).

Another aspect that can achieve the above object of the present invention is a polishing composition to be used to polish an object to be polished containing a resin material and a metallic material, the polishing composition containing abrasives, a second amine compound having two or more amino groups (—NH₂), and a dispersion medium.

### DESCRIPTION OF EMBODIMENTS

Hereinbelow, embodiments of the present invention will be described. The embodiments described herein are exemplified to embody the technical idea of the present invention and are not intended to limit the present invention. Therefore, other implementable embodiments, methods of use, and operation techniques conceivable by those skilled in the art without departing from the gist of the present invention are all included in the scope and gist of the present invention and are included in the invention described in the claims and the equivalent scope thereof. The embodiments described herein can freely be combined to provide other embodiments.

The phrase “X to Y” used herein to indicate a range includes X and Y and means “X or more and Y or less”. Unless otherwise specified, operation and measurement of physical properties etc. are performed under conditions of room temperature (20 °C or higher and 25 °C or lower)/relative humidity of 40% RH or more and 50% RH or less.

A first aspect of the present invention (first polishing composition) relates to a polishing composition to be used to polish an object to be polished containing a resin material and a metallic material, the polishing composition containing abrasives, a first amine compound having 0 or 1 amino group (—NH₂), a second amine compound having two or more amino groups (—NH₂), and a dispersion medium. When such two or more specific amine compounds as described above are used in combination, the polishing removal rate of a metallic material relative to the polishing removal rate of a resin material can appropriately be adjusted while a high polishing removal rate is kept during polishing of an object to be polished containing a resin material and a metallic material.

A second aspect of the present invention (second polishing composition) relates to a polishing composition to be used to polish an object to be polished containing a resin material and a metallic material, the polishing composition containing abrasives, a second amine compound having two or more amino groups (—NH₂), and a dispersion medium. When such a specific amine compound as described above is used, the polishing removal rate of a metallic material relative to the polishing removal rate of a resin material can appropriately be adjusted while a high polishing removal rate is kept during polishing of an object to be polished containing a resin material and a metallic material.

When a compound having nucleophilicity is present during polishing, the binding of a resin material is weakened, which makes it possible to promote polishing removal of the resin material. The first amine compound has high nucleophilicity for a resin material, which makes it possible to preferentially polish a resin material. Polishing of a metallic material is considered to be promoted when a compound that forms a complex with a metal ion is present. Therefore, the present inventor has studied a compound that can be expected to act on a metallic material while acting also on a resin material. As a result, the present inventor has found that the use of the second amine compound having two or more amino groups (—NH₂) makes it possible to efficiently polish both a resin material and a metallic material. The reason why the second amine compound promotes polishing of a resin material is considered to be the same as the reason described above with reference to the first amine compound. The reason why the second amine compound promotes polishing of a metallic material is considered to be that since the second amine compound has two amino groups (—NH₂), a complex is effectively formed with a metal ion derived from the metallic material so that polishing is promoted.

The present inventor has found that the use of the second amine compound makes it possible to efficiently polish both a resin material and a metallic material. Also, the present inventor has found that a combination of the first amine compound and the second amine compound makes it possible to appropriately adjust the polishing removal rate of a resin material and the polishing removal rate of a metallic material.

Specifically, the present inventor has found that the second amine compound can adjust the ratio of the polishing removal rate of a resin material to the polishing removal rate of a metallic material within an appropriate range (e.g., 0.4 or more and 2.0 or less) and that a combination of the first amine compound and the second amine compound makes it possible to adjust the ratio of the polishing removal rate of a resin material to the polishing removal rate of a metallic material within an appropriate range (e.g., 0.4 or more and 2.0 or less).

A detailed mechanism based on which the above object can be achieved by the polishing composition according to the present aspect is not clear but is presumed by the present inventor as described above. The above mechanism is based on the presumption, and whether or not the presumption is correct does not affect the technical scope of the present invention.

The polishing composition according to the present aspect has two modes: a first aspect (first polishing composition) and a second aspect (second polishing composition). These two aspects are different in whether or not the polishing composition contains a first amine compound as an amine compound, but other configurations (components other than the first amine compound and their contents) are common. Hereinbelow, unless otherwise specified, the configurations disclosed herein are common to the first polishing composition and the second polishing composition.

The phrase “the polishing removal rate of a metallic material relative to the polishing removal rate of a resin material is appropriately adjusted” herein has the same meaning as the phrase “the polishing removal rate of a resin material relative to the polishing removal rate of a metallic material is adjusted within an appropriate range (e.g., 0.4 or more and 2.0 or less)”. Further, the term “polishing removal rate” has herein the same meaning as the term “polishing rate”.

Hereinbelow, each of the components contained in the polishing composition according to the present aspect will be described in detail.

### <Object to be Polished>

An object to be polished for which the polishing composition according to the present aspect is used contains a resin material and a metallic material. The polishing composition according to the present aspect is particularly suitable for polishing a substrate including a patterned structure formed by a material containing a resin material and a metallic material, and the technical effect of the present invention is fully exerted when such a substrate is polished.

The resin material contained in the object to be polished is not limited, and examples thereof include polyethylene terephthalate (PET), polybenzoxazole (PBO), polybutylene terephthalate (PBT), polyimide (PI), polyamide (PA), an epoxy resin, a urethane acrylate resin, an unsaturated polyester resin, a phenol resin, a polynorbornene resin, polyacetal (POM), polycarbonate (PC), modified polyphenylene ether (m-PPE), ultra-high molecular weight polyethylene (UHMWPE), syndiotactic polystyrene (SPS), amorphous polyarylate (PAR), polysulfone (PSF), polyether sulfone (PES), polyphenylene sulfide (PPS), polyetheretherketone (PEEK), polyetherimide (PEI), benzocyclobutene (BCB), a fluorine resin, and a liquid crystal polymer (LCP). Among them, polyimide (PI), an epoxy resin, a urethane acrylate resin, and benzocyclobutene (BCB) are preferred. These resin materials may be used singly or in combination of two or more of them. According to some embodiments of the polishing composition according to the present aspect, the resin material contains polyimide (PI). When polyimide (PI) is contained, the effect of polishing a resin material at high polishing removal rate and reducing the polishing removal rate of a metallic material can efficiently be obtained.

The object to be polished contains a metallic material. When a general polishing composition is used, the removal rate of a metallic material is different from that of a resin material. That is, when a patterned structure containing a resin material and a metallic material is polished, a step difference is likely to be generated due to a difference between the removal rate of the metallic material and the removal rate of the resin material. The polishing composition according to the present aspect makes it possible to adjust the polishing removal rate of a resin material relative to the removal rate of a metallic material within an appropriate range while polishing an object to be polished at high polishing removal rate. This eventually makes it possible to avoid or prevent generation of a step difference.

The metallic material is not limited, and examples thereof include magnesium (Mg), aluminum (Al), titanium (Ti), chromium (Cr), manganese (Mn), iron (Fe), cobalt (Co), nickel (Ni), copper (Cu), zinc (Zn), zirconium (Zr), gold (Au), silver (Ag), platinum (Pt), iridium (Ir), bismuth (Bi), niobium (Ni), molybdenum (Mo), tin (Sn), tungsten (W), and lead (Pb). Among them, transition metals (especially, Group 6, Group 9, and Group 11), Group 13 metals, and Group 14 metals are preferred, and copper, cobalt, tungsten, aluminum, and tin are preferred. The metallic material may be, for example, a metal consisting of any single metallic element or an alloy consisting of any metallic element and one or more other elements. The above-mentioned metallic materials may be used singly or in combination of two or more of them.

<Polishing composition>

[Abrasives]

The abrasives contained in the polishing composition according to the present aspect are not limited, and examples thereof include silica particles, alumina particles, and a combination of them. The abrasives mechanically polish an object to be polished and increase a polishing removal rate. The abrasives preferably contain alumina particles. The alumina particles have adequate hardness and are therefore highly effective at increasing a polishing removal rate, especially the polishing removal rate of any of various materials containing a resin material.

In some embodiments, the average particle size (average secondary particle size) of the alumina particles is preferably 2.0 μm or less, more preferably 1.5 μm or less, even more preferably 1.0 μm or less, particularly preferably 0.8 μm or less, most preferably 0.4 μm or less. The average particle size of the alumina particles is preferably 0.01 μm or more, more preferably 0.02 μm or more, even more preferably 0.05 μm or more, particularly preferably 0.1 μm or more, most preferably 0.2 μm or more. When the average particle size of the alumina particles falls within the above range, the polishing removal rate of a resin material relative to the polishing removal rate of a metallic material is easily adjusted within an appropriate range (e.g., 0.4 or more and 2.0 or less). For example, the average particle size of the alumina particles is preferably 0.01 μm or more and 2.0 μm or less, more preferably 0.02 μm or more and 1.5 μm or less, even more preferably 0.05 μm or more and 1.0 μm or less, particularly preferably 0.1 μm or more and 0.8 μm or less, most preferably 0.2 μm or more and 0.4 μm or less.

In some embodiments, the average particle size (average secondary particle size) of the alumina particles is preferably less than 2.8 μm. The average particle size of the alumina particles is preferably 2.0 μm or less, more preferably less than 1.5 μm, even more preferably less than 1.2 μm, particularly preferably less than 0.8 μm. The average particle size of the alumina particles is preferably 0.1 μm or more, more preferably 0.2 μm or more, even more preferably more than 0.2 μm, particularly preferably 0.3 μm or more. When the average particle size of the alumina particles falls within the above range, the polishing removal rate of a resin material relative to the polishing removal rate of a metallic material is easily adjusted within an appropriate range (e.g., 0.4 or more and 2.0 or less). Further, there is also an effect such that a good balance can be achieved between an increase in polishing removal rate and a reduction in surface roughness. For example, the average particle size of the alumina particles is preferably 0.1 μm or more and 2.0 μm or less, more preferably 0.2 μm or more and less than 1.5 μm, even more preferably more than 0.2 μm and less than 1.2 μm, particularly preferably 0.3 μm or more and less than 0.8 μm.

The average particle size (average secondary particle size) of the alumina particles refers to a particle size (D₅₀) when a cumulative volume percentage from a small particle size side in a volume-based particle size distribution reaches 50%. Here, the D₅₀ of the alumina particles is determined by, for example, a dynamic light scattering method, a laser diffraction method, a laser scattering method, or a pore electric resistance method.

The alumina particles are not limited and are, for example, alumina particles containing at least one selected from the group consisting of «-alumina, γ-alumina, 8-alumina, O-alumina, n-alumina, or K-alumina.

The concentration (content) of the alumina particles is not limited but is preferably 0.01% by mass or more, more preferably 0.1% by mass or more, even more preferably 0.5% by mass or more, particularly preferably 1% by mass or more, particularly preferably 1.5% by mass or more relative to the total mass of the polishing composition. A polishing removal rate increases as the concentration of the alumina particles increases. Further, the concentration (content) of the alumina particles is preferably 25% by mass or less, more preferably 15% by mass or less, even more preferably 10% by mass or less, still even more preferably less than 9% by mass, particularly preferably 8% by mass or less relative to the total mass of the polishing composition. When the concentration (content) of the alumina particles falls within the above range, the polishing removal rate of a resin material relative to the polishing removal rate of a metallic material is easily adjusted within an appropriate range (e.g., 0.4 or more and 2.0 or less). Further, there is also an effect such that surface roughness is further reduced and the occurrence of a defect such as a scratch is further reduced. For example, the concentration (content) of the alumina particles is preferably 0.01% by mass or more and 25% by mass or less, more preferably 0.1% by mass or more and 15% by mass or less, even more preferably 0.5% by mass or more and 10% by mass or less, particularly preferably 1% by mass or more and less than 9% by mass, particularly preferably 1.5% by mass or more and 8% by mass or less relative to the total mass of the polishing composition. When the concentration (content) of the alumina particles falls within the above range, the polishing removal rate of a resin material relative to the polishing removal rate of a metallic material is easily adjusted within an appropriate range (e.g., 0.4 or more and 2.0 or less). Further, there is also an effect such that a good balance can be achieved between an increase in polishing removal rate and a reduction in surface roughness.

The alumina particles can easily be produced by reference to a known production method (e.g., Japanese Patent Laid-Open No. 2017-190267) as appropriate. Alternatively, the alumina particles may be a commercially-available product.

It should be noted that the alumina particles to be used may be composed of only one type of alumina particles or may be a combination of two or more types of alumina particles.

### [Amine Compound]

The polishing composition according to the present aspect contains an amine compound. Here, the first polishing composition of the present aspect contains, as the amine compound, a first amine compound and a second amine compound. The second polishing composition of the present aspect contains, as the amine compound, a second amine compound. In some embodiments, the second polishing composition contains, as the amine compound, only a second amine compound. As for the amine compound, the first polishing composition and the second polishing composition will be described separately.

### First Polishing Composition

### [First Amine Compound]

The polishing composition according to the present aspect contains a first amine compound having 0 or 1 amino group (—NH₂). Here, the amine compound having 0 amino groups (—NH₂) refers to a secondary amine and/or a tertiary amine having no amino group (—NH₂). The first amine compound increases the polishing removal rate of a resin material but has no effect on or only slightly increases the polishing removal rate of a metallic material. Therefore, the first amine compound reduces the ratio of the polishing removal rate of a metallic material to the polishing removal rate of a resin material. That is, the first amine compound increases the ratio of the polishing removal rate of a resin material to the polishing removal rate of a metallic material. The first amine compound having 0 or 1 amino group (—NH₂) is, for example, at least one selected from the group consisting of: an amino alcohol; an aliphatic amine compound; or an aromatic group-containing amine compound.

According to one embodiment, the first amine compound is not limited as long as it has 0 or 1 amino group (—NH₂), but the number of nitrogen atoms of the first amine compound is preferably 1 or more and 4 or less, more preferably 1 or more and 3 or less, even more preferably 1 or 2, particularly preferably 1.

The first amine compound having no amino group (—NH₂) is, for example, at least one selected from the group consisting of: an amino alcohol having a secondary amino group (—NHR) and/or a tertiary amino group (—NR′R″); an aliphatic amine compound having a secondary amino group and/or a tertiary amino group; or an aromatic group-containing amine compound having a secondary amino group and/or a tertiary amino group. Among them, preferred are an amino alcohol having a secondary amino group and/or a tertiary amino group and an aliphatic amine compound having a secondary amino group and/or a tertiary amino group, and more preferred is an amino alcohol having a secondary amino group and/or a tertiary amino group. The aliphatic amine compound may be a linear, branched, or cyclic aliphatic amine compound. Here, the R, R′, and R″ are not hydrogen atoms.

The first amine compound having 1 amino group (—NH₂) is not limited as long as it has 1 amino group (—NH₂), and may further have a secondary amino group and/or a tertiary amino group. The first amine compound having 1 amino group (—NH₂) is, for example, at least one selected from the group consisting of: an amino alcohol having an amino group (—NH₂); an aliphatic amine compound having an amino group (—NH₂); or an aromatic group-containing amine compound having an amino group (—NH₂). Among them, preferred are an amino alcohol having an amino group (—NH₂) and an aliphatic amine compound having an amino group (—NH₂), and more preferred is an amino alcohol having an amino group (—NH₂). The aliphatic amine compound may be a linear, branched, or cyclic aliphatic amine compound. The aliphatic amine compound herein means an aliphatic amine containing no aromatic group.

### Amino Alcohol

The amino alcohol as a first amine compound is not limited as long as it has 0 or 1 amino group (—NH₂) and 1 or more hydroxyl (—OH) groups. The number of hydroxyl (—OH) groups of the amino alcohol as a first amine compound is preferably 1 or more and 4 or less, more preferably 1 or more and 3 or less, even more preferably 1 or 2. The amino alcohol as a first amine compound may be linear, branched, or cyclic but is preferably linear or branched.

The amino alcohol as a first amine compound is not limited as long as it has 0 or 1 amino group (—NH₂) and 1 or more hydroxyl (—OH) groups, but preferably contains a hydrocarbon group having 1 or more and 10 or less carbon atoms, more preferably contains a hydrocarbon group having 1 or more and 8 or less carbon atoms, and even more preferably contains a hydrocarbon group having 1 or more and 5 or less carbon atoms. Further, the amino alcohol as a first amine compound preferably contains a hydrocarbon group having 1 or more and 20 or less carbon atoms, more preferably contains a hydrocarbon group having 1 or more and 10 or less carbon atoms, and even more preferably contains a hydrocarbon group having 1 or more and 8 or less carbon atoms in the whole molecule. According to one embodiment, the amino alcohol as a first amine compound contains, in the whole molecule, a hydrocarbon group having 1 or more and 6 or less carbon atoms, a hydrocarbon group having 1 or more and 5 or less carbon atoms, a hydrocarbon group having 1 or more and 4 or less carbon atoms, or a hydrocarbon group having 1 or more and 3 or less carbon atoms.

According to one embodiment, the amino alcohol as a first amine compound has 0 or 1 amino group (—NH₂) and 1 or more (preferably 1 or more and 4 or less, more preferably 1 or more and 3 or less, even more preferably 1 or 2) hydroxyl (—OH) groups and contains, in the whole molecule, a hydrocarbon group having 1 or more and 6 or less (preferably 1 or more and 5 or less, more preferably 1 or more and 4 or less, even more preferably 1 or more and 3 or less) carbon atoms. According to one embodiment, the number of nitrogen atoms of the amino alcohol as a first amine compound may be 1 or more and 4 or less, 1 or more and 3 or less, or 1 or 2.

According to one embodiment, the first amine compound is an amino alcohol having 1 or more and 6 or less (preferably 1 or more and 5 or less, more preferably 1 or more and 4 or less, even more preferably 1 or more and 3 or less) carbon atoms.

Examples of the amino alcohol having no amino group (—NH₂) but having a secondary amino group and/or a tertiary amino group as a first amine compound include triethanolamine, 2-dimethylaminoethanol, 2-(methylamino)-2-methyl-1-propanol, and 2-(dimethylamino)-2-methyl-1-propanol.

Examples of the amino alcohol having 1 amino group (—NH₂) and optionally having a secondary amino group and/or a tertiary amino group as a first amine compound include 2-aminoethanol, 1-amino-2-propanol, 2-amino-1-propanol, 3-amino-1-propanol, 4-amino-1-butanol, 3-amino-1-butanol, 2-amino-1-butanol, 1-amino-2-butanol, 2-(2-aminoethylamino) ethanol, 2-(2-aminoethoxy) ethanol (another name: diethylene glycolamine), trishydroxymethylaminomethane, 2-amino-2-methyl-1-propanol, 1-dimethylamino-2-propanol, 2-amino-2-methyl-1,3-propanediol, and 2-amino-2-ethyl-1,3-propanediol.

### Aliphatic Amine Compound

The aliphatic amine compound as a first amine compound is a compound having 0 or 1 amino group (—NH₂) and an aliphatic hydrocarbon group.

Examples of the aliphatic amine compound having no amino group (—NH₂) but having a secondary amino group and/or a tertiary amino group as a first amine compound include linear, branched, or cyclic amine compounds such as N,N-diisopropylethylamine, tri-n-octylamine, pentamethyldiethylenetriamine, homopiperazine, N-methylpiperazine, trimethylamine, and triethylamine.

Examples of the aliphatic amine compound having 1 amino group (—NH₂) as a first amine compound include ethylamine, n-propylamine, isopropylamine, tert-butylamine, 3-diethylaminopropylamine, 2-ethylhexylamine, aminomethylpiperazine, and aminoethylpiperazine (another name: N-(2-aminoethyl) piperazine).

### Aromatic Group-Containing Amine Compound

The aromatic group-containing amine compound as a first amine compound is a compound having 0 or 1 amino group (—NH₂) and an aromatic group.

Examples of the aromatic group-containing amine compound having no amino group (—NH₂) as a first amine compound include pyrrole, diphenylamine, and dibenzylamine.

Examples of the aromatic group-containing amine compound having 1 amino group (—NH₂) as a first amine compound include aniline, 3-aminomethylpyridine, and benzylamine.

According to one embodiment, the first amine compound contains aminoethanol, aminopropanol, aminobutanol, aminoethylpiperazine, triethanolamine, and 2-(2-aminoethylamino) ethanol. For example, the first amine compound contains 2-aminoethanol, 1-amino-2-propanol, aminoethylpiperazine, triethanolamine, and 2-(2-aminoethylamino) ethanol. The first amine compounds may be used singly or in combination of two or more of them.

The first amine compound is not limited as long as it has 0 or 1 amino group (—NH₂), but preferably contains a hydrocarbon group having 1 or more and 10 or less carbon atoms, more preferably contains a hydrocarbon group having 1 or more and 8 or less carbon atoms, even more preferably contains a hydrocarbon group having 1 or more and 5 or less carbon atoms. Further, the first amine compound preferably contains a hydrocarbon group having 1 or more and 20 or less carbon atoms, more preferably contains a hydrocarbon group having 1 or more and 10 or less carbon atoms, and even more preferably contains a hydrocarbon group having 1 or more and 8 or less carbon atoms in the whole molecule.

The molecular weight of the first amine compound is not limited, but is preferably 300 or less, more preferably 250 or less, even more preferably 200 or less, particularly preferably 180 or less, most preferably 150 or less. The lower limit of molecular weight of the first amine compound is not limited but is preferably 60 or more.

The content of the first amine compound in the polishing composition is preferably 0.05% by mass or more, more preferably 0.5% by mass or more, even more preferably 1% by mass or more, particularly preferably 2% by mass or more, most preferably 3% by mass or more relative to the total mass of the polishing composition. The upper limit of content of the first amine compound is preferably 25% by mass or less, more preferably 22% by mass or less, even more preferably 20% by mass or less, particularly preferably 18% by mass or less, most preferably 15% by mass or less relative to the total mass of the polishing composition. It should be noted that when two or more types of first amine compounds are used, the content represents the total amount of them.

### [Second Amine Compound]

The polishing composition according to the present aspect contains a second amine compound having 2 or more amino groups (—NH₂). The second amine compound increases the polishing removal rate of a resin material and further increases the polishing removal rate of a metallic material. Therefore, the second amine compound increases the ratio of the polishing removal rate of a metallic material to the polishing removal rate of a resin material. That is, the second amine compound reduces the ratio of the polishing removal rate of a resin material to the polishing removal rate of a metallic material.

The second amine compound may have not only an amino group (—NH₂) but also a secondary amino group and/or a tertiary amino group as long as it has two or more amino groups (—NH₂). The second amine compound is at least one selected from the group consisting of: an amino alcohol having 2 or more amino groups (—NH₂) (and optionally having a secondary amino group and/or a tertiary amino group); an aliphatic amine compound having 2 or more amino groups (—NH₂) (and optionally having a secondary amino group and/or a tertiary amino group); or an aromatic group-containing amine compound having 2 or more amino groups (—NH₂) (and optionally having a secondary amino group and/or a tertiary amino group). Among them, preferred are an amino alcohol having 2 or more amino groups (—NH₂) (and optionally having a secondary amino group and/or a tertiary amino group) and an aliphatic amino compound having 2 or more amino groups (—NH₂) (and optionally having a secondary amino group and/or a tertiary amino group), and more preferred is an aliphatic amine compound having 2 or more amino groups (—NH₂) (and optionally having a secondary amino group and/or a tertiary amino group). The aliphatic amine compound may be a linear, branched, or cyclic aliphatic amine compound.

The second amine compound having 2 or more amino groups (—NH₂) is, for example, at least one selected from the group consisting of: an amino alcohol, an aliphatic amine compound; or an aromatic group-containing amine compound.

According to one embodiment, the second amine compound is not limited as long as it has 2 or more amino groups (—NH₂), but the number of nitrogen atoms of the second amine compound is preferably 2 or more and 5 or less, more preferably 2 or more and 4 or less, even more preferably 2 or 3.

### Amino Alcohol

The amino alcohol as a second amine compound is not limited as long as it has 2 or more amino groups (—NH₂). The amino alcohol as a second amine compound may be linear, branched, or cyclic but is preferably linear or branched.

Examples of the amino alcohol having 2 or more amino groups (—NH₂) (and optionally having a secondary amino group and/or a tertiary amino group) as a second amine compound include 1,3-diamino-2-propanol and 1,4-diamino-2-butanol.

### Aliphatic Amine Compound

The aliphatic amine compound as a second amine compound is not limited as long as it has 2 or more amino groups (—NH₂). The aliphatic amine compound as a second amine compound may be linear, branched, or cyclic but is preferably linear or branched.

The aliphatic amine compound as a second amine compound is not limited as long as it has 2 or more amino groups (—NH₂), but preferably contains an aliphatic hydrocarbon group having 1 or more and 10 or less carbon atoms, more preferably contains an aliphatic hydrocarbon group having 1 or more and 8 or less carbon atoms, and even more preferably contains an aliphatic hydrocarbon group having 1 or more and 5 or less carbon atoms. Further, the aliphatic amine compound as a second amine compound preferably contains an aliphatic hydrocarbon group having 1 or more and 20 or less carbon atoms, more preferably contains an aliphatic hydrocarbon group having 1 or more and 10 or less carbon atoms, and even more preferably contains an aliphatic hydrocarbon group having 1 or more and 8 or less carbon atoms in the whole molecule. According to one embodiment, the aliphatic amine compound as a second amine compound contains, in the whole molecule, an aliphatic hydrocarbon group having 1 or more and 6 or less carbon atoms, an aliphatic hydrocarbon group having 1 or more and 5 or less carbon atoms, an aliphatic hydrocarbon group having 1 or more and 4 or less carbon atoms, or an aliphatic hydrocarbon group having 2 or more and 4 or less carbon atoms.

According to one embodiment, the aliphatic amine compound as a second amine compound has 2 or more amino groups (—NH₂) and contains an aliphatic hydrocarbon group having 1 or more and 6 or less (preferably 1 or more and 5 or less, more preferably 1 or more and 4 or less, even more preferably 2 or more and 4 or less) carbon atoms in the whole molecule. Further, according to one embodiment, the number of nitrogen atoms of the aliphatic amine compound as a second amine compound may be 1 or more and 4 or less, 1 or more and 3 or less, or 2 or 3.

According to one embodiment, the second amine compound is an aliphatic amine compound having 1 or more and 6 or less (preferably 1 or more and 5 or less, more preferably 1 or more and 4 or less, even more preferably 1 or more and 3 or less) carbon atoms.

Examples of the aliphatic amine compound having 2 or more amino groups (—NH₂) (and optionally having a secondary amino group and/or a tertiary amino group) as a second amine compound include ethylenediamine, diethylenetriamine, 1,2-diamino-2-methylpropane, 1,3-propanediamine, 1,2-propanediamine, 1,4-diaminobutane, 1,3-diaminobutane, 1,2-diaminobutane, 1,5-diaminopentane, 1,3-diaminopentane, triethylenetetramine, tetraethylenepentamine, hexamethylenediamine, 1,3-bisaminomethylcyclohexane, 1,2-cyclohexanediamine, 1,4-cyclohexanediamine, and norbornanediamine.

### Aromatic Group-Containing Amine Compound

The aromatic group-containing amine compound as a second amine compound is a compound having 2 or more amino groups (—NH₂) and an aromatic group.

Examples of the aromatic group-containing amine compound having 2 or more amino groups (—NH₂) (and optionally having a secondary amino group and/or a tertiary amino group) as a second amine compound include p-phenylenediamine, meta-xylenediamine, and 4,4′-diaminodiphenylmethane.

According to one embodiment, the second amine compound contains ethylenediamine, diethylenetriamine, diamino-2-methylpropane, cyclohexanediamine, propanediamine, and diaminobutane. For example, the second amine compound contains ethylenediamine, diethylenetriamine, 1,2-diamino-2-methylpropane, 1,4-cyclohexanediamine, 1,3-propanediamine, and 1,2-propanediamine. The second amine compounds may be used singly or in combination of two or more of them.

The second amine compound is not limited as long as it has 2 or more amino groups (—NH₂), but preferably contains a hydrocarbon group having 1 or more and 10 or less carbon atoms, more preferably contains a hydrocarbon group having 1 or more and 8 or less carbon atoms, and even more preferably contains a hydrocarbon group having 1 or more and 5 or less carbon atoms. Further, the second amine compound preferably contains a hydrocarbon group having 1 or more and 20 or less carbon atoms, more preferably contains a hydrocarbon group having 1 or more and 10 or less carbon atoms, and even more preferably contains a hydrocarbon group having 1 or more and 8 or less carbon atoms in the whole molecule.

The molecular weight of the second amine compound is not limited but is preferably 300 or less, more preferably 250 or less, even more preferably 200 or less, particularly preferably 180 or less, most preferably 150 or less. The lower limit of molecular weight of the second amine compound is not limited but is preferably 60 or more.

The content of the second amine compound in the polishing composition is preferably 0.05% by mass or more, more preferably 0.5% by mass or more, even more preferably 1% by mass or more, particularly preferably 2% by mass or more, most preferably 3% by mass or more relative to the total mass of the polishing composition. The upper limit of content of the second amine compound is preferably 25% by mass or less, more preferably 22% by mass or less, even more preferably 20% by mass or less, particularly preferably 18% by mass or less, most preferably 15% by mass or less relative to the total mass of the polishing composition. It should be noted that when two or more types of second amine compounds are used, the content represents the total amount of them.

The total content of the first amine compound and the second amine compound in the polishing composition is preferably 0.05% by mass or more, more preferably 0.5% by mass or more, even more preferably 1% by mass or more, particularly preferably 2% by mass or more, most preferably 3% by mass or more relative to the total mass of the polishing composition. The upper limit of total content of the first amine compound and the second amine compound is preferably 25% by mass or less, more preferably 22% by mass or less, even more preferably 20% by mass or less, particularly preferably 18% by mass or less, most preferably 15% by mass or less relative to the total mass of the polishing composition.

By adjusting, for example, the content of each of the first amine compound and the second amine compound, the ratio of the polishing removal rate of a metallic material to the polishing removal rate of a resin material can be adjusted. The ratio (weight ratio) of the content of the second amine compound to the content of the first amine compound is not limited but is preferably 10:1 to 1:10, more preferably 5:1 to 1:5, particularly preferably 3:1 to 1:3. When the ratio falls within such a range, an appropriate balance is easily achieved between the polishing removal rate of a resin material and the polishing removal rate of a metallic material.

According to one embodiment, the first amine compound is an amino alcohol and the second amine compound is an aliphatic amine compound. In this case, the amino alcohol as a first amine compound has 0 or 1 amino group (—NH₂) and 1 or more (preferably 1 or more and 4 or less, more preferably 1 or more and 3 or less, even more preferably 1 or 2) hydroxyl (—OH) groups and contains, in the whole molecule, a hydrocarbon group having 1 or more and 6 or less (preferably 1 or more and 5 or less, more preferably 1 or more and 4 or less, even more preferably 1 or more and 3 or less) carbon atoms, and the aliphatic amine compound as a second amine compound has 2 or more amino groups (—NH₂) and contains, in the whole molecule, an aliphatic hydrocarbon group having 1 or more and 6 or less (preferably 1 or more and 5 or less, more preferably 1 or more and 4 or less, even more preferably 2 or more and 4 or less) carbon atoms. According to one embodiment, the number of nitrogen atoms of the amino alcohol as a first amine compound may be 1 or more and 4 or less, 1 or more and 3 or less, or 1 or 2, and the number of nitrogen atoms of the aliphatic amine compound as a second amine compound may be 1 or more and 4 or less, 1 or more and 3 or less, or 2 or 3.

According to one embodiment, the first amine compound is an amino alcohol having 1 or more and 6 or less (preferably 1 or more and 5 or less, more preferably 1 or more and 4 or less, even more preferably 1 or more and 3 or less) carbon atoms, and the second amine compound is an aliphatic amine compound having 1 or more and 6 or less (preferably 1 or more and 5 or less, more preferably 1 or more and 4 or less, even more preferably 1 or more and 3 or less) carbon atoms.

According to one embodiment, the first amine compound contains at least one selected from the group consisting of 2-aminoethanol, 1-amino-2-propanol, aminoethylpiperazine, triethanolamine, or 2-(2-aminoethylamino) ethanol, and the second amine compound contains at least one selected from the group consisting of ethylenediamine, diethylenetriamine, 1,2-diamino-2-methylpropane, 1,4-cyclohexanediamine, 1,3-propanediamine, or 1,2-propanediamine.

### Second Polishing Composition

### [Second Amine Compound (Third Amine Compound)]

The second polishing composition contains, as the amine compound, a second amine compound. The second amine compound in the second polishing composition makes it possible to adjust the ratio of the polishing removal rate of a resin material to the polishing removal rate of a metallic material within an appropriate range. Hereinbelow, the second amine compound used for the second polishing composition may be referred to as a third amine compound for convenience.

The third amine compound to be used is the same as the compound described above with reference to the second amine compound. Specifically, the third amine compound may have not only an amino group (—NH₂) but also a secondary amino group and/or a tertiary amino group as long as it has 2 or more amino groups (—NH₂). The third amine compound (second amine compound) is at least one selected from the group consisting of: an amino alcohol having 2 or more amino groups (—NH₂) (and optionally having a secondary amino group and/or a tertiary amino group); an aliphatic amine compound having 2 or more amino groups (—NH₂) (and optionally having a secondary amino group and/or a tertiary amino group); or an aromatic group-containing amine compound having 2 or more amino groups (—NH₂) (and optionally having a secondary amino group and/or a tertiary amino group). Among them, preferred are an amino alcohol having 2 or more amino groups (—NH₂) (and optionally having a secondary amino group and/or a tertiary amino group) and an aliphatic amine compound having 2 or more amino groups (—NH₂) (and optionally having a secondary amino group and/or a tertiary amino group), and more preferred is an aliphatic amine compound having 2 or more amino groups (—NH₂) (and optionally having a secondary amino group and/or a tertiary amino group). The aliphatic amine compound may be a linear, branched, or cyclic aliphatic amine compound. Examples of the amino alcohol, the aliphatic amine compound, and the aromatic group-containing amine compound to be used as a third amine compound are the same as those described above with reference to the second amine compound and are therefore omitted here.

In some embodiments, the third amine compound (second amine compound) is preferably an aliphatic amine, an aliphatic amine having 2 or more and 10 or less carbon atoms, or an aliphatic amine having 3 or more and 8 or less carbon atoms. In order to further exert the effect of polishing a resin material at high polishing removal rate and reducing the polishing removal rate of a metallic material, 2 amino groups (—NH₂) in the third amine compound (second amine compound) are preferably linked together by a carbon chain (preferably by an alkylene chain). Specifically, 2 amino groups (—NH₂) may be linked together by a carbon chain (preferably by an alkylene chain) having 2 or more and 10 or less carbon atoms, 2 amino groups (—NH₂) may be linked together by a carbon chain (preferably by an alkylene chain) having 3 or more and 8 or less carbon atoms, 2 amino groups may be linked together by a carbon chain (preferably by an alkylene chain) having 3 or more and 5 or less carbon atoms, or 2 amino groups (—NH₂) may be linked together by a carbon chain (preferably by an alkylene chain) having 3 or 4 carbon atoms.

According to one embodiment, the third amine compound (second amine compound) is an aliphatic amine compound having 1 or more and 6 or less (preferably 1 or more and 5 or less, more preferably 1 or more and 4 or less, even more preferably 1 or more and 3 or less) carbon atoms.

Examples of the third amine compound (second amine compound) include ethylenediamine, diethylenetriamine, 1,2-diamino-2-methylpropane, 1,3-propanediamine, 1,2-propanediamine, triethylenetetramine, tetraethylenepentamine, meta-xylenediamine, 1,3-bisaminomethylcyclohexane, 1,4-cyclohexanediamine, and norbornanediamine. Among these third amine compounds, preferred are ethylenediamine, diethylenetriamine, 1,2-diamino-2-methylpropane, 1,4-cyclohexanediamine, 1,3-propanediamine, 1,2-propanediamine, triethylenetetramine, tetraethylenepentamine, and meta-xylenediamine, and more preferred are 1,3-propanediamine and 1,2-propanediamine.

The molecular weight of the third amine compound (second amine compound) is not limited but is preferably 300 or less, more preferably 250 or less, even more preferably 200 or less, particularly preferably 180 or less, most preferably 150 or less. The lower limit of molecular weight of the third amine compound (second amine compound) is not limited but is preferably 60 or more.

The content of the third amine compound (second amine compound) in the polishing composition is preferably 0.05% by mass or more, more preferably 0.5% by mass or more, even more preferably 1% by mass or more, particularly preferably 2% by mass or more, most preferably 3% by mass or more relative to the total mass of the polishing composition. The upper limit of content of the third amine compound (second amine compound) is preferably 25% by mass or less, more preferably 22% by mass or less, even more preferably 20% by mass or less, particularly preferably 18% by mass or less, most preferably 15% by mass or less relative to the total mass of the polishing composition. It should be noted that when two or more types of third amine compounds are used, the content represents the total amount of them.

### [Dispersion Medium]

The polishing composition according to the present aspect contains a dispersion medium. The dispersion medium disperses or dissolves each component.

The dispersion medium preferably contains water. Further, from the viewpoint of preventing the effect of impurities on other components of the polishing composition, water with purity as high as possible is preferably used. Specifically, pure water or ultra-pure water obtained by removing impurity ions with an ion exchange resin and then removing foreign matter by passage through a filter or distilled water is preferred. As the dispersion medium, an organic solvent or the like may further be contained for the purpose of controlling dispersibility of other components of the polishing composition.

### [pH Adjusting Agent]

In the polishing composition according to the present aspect, each of the amine compounds described above also plays a role of a pH adjusting agent. When it is difficult to achieve a desired pH only by the amine compound, pH is preferably adjusted by adding a pH adjusting agent to the extent that the effect of polishing a resin material at high polishing removal rate and reducing the polishing removal rate of a metallic material is not impaired.

That is, the polishing composition according to some embodiments preferably further contains a pH adjusting agent. By selecting the type of the pH adjusting agent and the amount of the pH adjusting agent to be added, the pH adjusting agent can contribute to adjustment of pH of the polishing composition.

The pH adjusting agent is not limited as long as it is a compound having the function of adjusting pH, and may be a known compound. The pH adjusting agent is not limited as long as it has the function of adjusting pH, and is, for example, an acid or an alkali.

The acid may be either an inorganic acid or an organic acid. Examples of the inorganic acid include, but are not limited to, sulfuric acid, nitric acid, boric acid, carbonic acid, hypophosphorous acid, phosphorous acid, and phosphoric acid. Examples of the organic acid include, but are not limited to, carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, methanesulfonic acid, ethanesulfonic acid, and isethionic acid. Among them, preferred are organic acids, and more preferred are malic acid, citric acid, and maleic acid. It should be noted that when an inorganic acid is used, preferred are nitric acid, sulfuric acid, and phosphoric acid.

Examples of the alkali include, but are not limited to, a hydroxide of an alkali metal or a salt thereof, a hydroxide of an alkaline-earth metal or a salt thereof, a quaternary ammonium compound or a salt thereof, and ammonia.

Specific examples of the alkali metal include potassium and sodium. Specific examples of the alkaline-earth metal include calcium and strontium. Specific examples of the salt include a carbonate, a hydrogencarbonate, a sulfate, and an acetate. Specific examples of the quaternary ammonium compound include tetramethylammonium, tetraethylammonium, tetrabutylammonium, and hydroxides thereof. Among these alkalis, potassium hydroxide or ammonia is preferred.

It should be noted that the pH adjusting agents may be used singly or in combination of two or more of them.

The pH of the polishing composition according to the present aspect is not limited. However, from the viewpoint of polishing removal rate, the polishing composition is preferably alkaline, and therefore the pH of the polishing composition is preferably 8 or more. The pH is more preferably 9 or more, even more preferably 10 or more, particularly preferably 11 or more. Further, from the viewpoint of the ratio between the polishing removal rate of a metallic material and the polishing removal rate of a resin material and surface roughness, the pH is preferably 14 or less, more preferably 13 or less, even more preferably 12 or less. The pH may be in the range of 8 or more and 14 or less but is preferably in the range of 9 or more and 13 or less, more preferably in the range of 10 or more and 12 or less. When the pH falls within the above range, the polishing removal rate of a resin material relative to the polishing removal rate of a metallic material is easily adjusted within an appropriate range (e.g., 0.4 or more and 2.0 or less). Further, there is also an effect such that a good balance can be achieved between an increase in polishing removal rate and a reduction in surface roughness. The content of the pH adjusting agent is not limited and is preferably set in such a manner that the value of pH falls within the above preferred range.

### [Other Components]

The polishing composition according to the present aspect may further contain known components such as abrasives other than those described above, a chelating agent, a thickener, an oxidizing agent, a dispersing agent, a surface protecting agent, a wetting agent, a surfactant, a water soluble polymer, a salt, an anticorrosive (antirust), an antiseptic agent, and an antifungal agent to the extent that the effect of polishing a resin material at high polishing removal rate and reducing the polishing removal rate of a metallic material is not impaired. The content of each of the other components may appropriately be set depending on the purpose of the component to be added. In some preferred embodiments of the polishing composition, a chelating agent, an oxidizing agent, a dispersing agent, a surface protecting agent, and an anticorrosive are contained.

In some embodiments, the polishing composition may contain a water soluble polymer such as polyvinyl pyrrolidone, pullulan, hydroxyethyl cellulose, polyvinyl alcohol, or polyacrylic acid and a salt such as potassium carbonate, sodium sulfate, potassium sulfate, ammonium nitrate, or ammonium sulfate from the viewpoint of adjusting the polishing removal rate of a metallic material relative to the polishing removal rate of a resin material.

In one embodiment of the first aspect, the polishing composition according to the present aspect (first polishing composition) is substantially composed of abrasives, a first amine compound, a second amine compound, a dispersion medium, and at least one selected from the group consisting of a pH adjusting agent. The phrase “substantially composed of abrasives, a first amine compound, a second amine compound, a dispersion medium, and at least one selected from the group consisting of a redispersing agent and a pH adjusting agent” herein means that the total content of the abrasives, the first amine compound, the second amine compound, the dispersion medium, and the pH adjusting agent exceeds 93% by mass relative to the polishing composition, and the total content preferably exceeds 95% by mass, more preferably exceeds 98%, and even more preferably exceeds 99% (upper limit: 100% by mass).

In one embodiment of the first aspect, the polishing composition according to the present aspect (first polishing composition) is a polishing composition to be directly used as a polishing liquid for polishing an object to be polished (which is typically a polishing liquid in a slurry state and may be referred to as a working slurry or a polishing slurry), and is composed of abrasives, a first amine compound, a second amine compound, a dispersion medium, and at least one additional component selected from the group consisting of a pH adjusting agent, a chelating agent, a thickener, an oxidizing agent, a dispersing agent, a surface protecting agent, a wetting agent, a surfactant, an anticorrosive (antirust), an antiseptic agent, and an antifungal agent. The content of the additional component is 0% by mass, more than 0% by mass and 7% by mass or less, more than 0% by mass and 5% by mass or less, more than 0% by mass and 3% by mass or less, or more than 0% by mass and 2% by mass or less relative to the polishing composition.

In another embodiment of the second aspect, the polishing composition according to the present aspect (second polishing composition) is substantially composed of abrasives, a second amine compound (third amine compound), a dispersion medium, and at least one selected from the group consisting of a pH adjusting agent. The phrase “substantially composed of abrasives, a second amine compound, a dispersion medium, and at least one selected from the group consisting of a redispersing agent and a pH adjusting agent” herein means that the total content of the abrasives, the second amine compound, the dispersion medium, and the pH adjusting agent exceeds 93% by mass relative to the polishing composition, and the total content preferably exceeds 95% by mass, more preferably exceeds 98%, and even more preferably exceeds 99% (upper limit: 100% by mass).

In another embodiment of the second aspect, the polishing composition according to the present aspect (second polishing composition) is a polishing composition to be directly used as a polishing liquid for polishing an object to be polished (which is typically a polishing liquid in a slurry state and may be referred to as a working slurry or a polishing slurry), and is composed of abrasives, a second amine compound (third amine compound), a dispersion medium, and at least one additional component selected from the group consisting of a pH adjusting agent, a chelating agent, a thickener, an oxidizing agent, a dispersing agent, a surface protecting agent, a wetting agent, a surfactant, an anticorrosive (antirust), an antiseptic agent, and an antifungal agent. The content of the additional component is 0% by mass, more than 0% by mass and 7% by mass or less, more than 0% by mass and 5% by mass or less, more than 0% by mass and 3% by mass or less, or more than 0% by mass and 2% by mass or less relative to the polishing composition.

### [Polishing Removal Rate]

In the present aspect, the polishing composition according to some embodiments can appropriately adjust the polishing removal rate of a resin material and the polishing removal rate of a metallic material. The polishing removal rate of a resin material is, for example, preferably 2.0 μm/min or more and 10.0 μm/min or less, more preferably 2.5 μm/min or more and 9.0 μm/min or less, even more preferably 3.0 μm/min or more and 8.0 μm/min or less. The polishing removal rate of a metallic material is, for example, preferably 2.0 μm/min or more and 10.0 μm/min or less, more preferably 2.5 μm/min or more and 9.0 μm/min or less, even more preferably 3.0 μm/min or more and 8.0 μm/min or less.

### [Polishing Removal Rate Ratio]

The polishing composition according to the present aspect can adjust the polishing removal rate of a resin material and the polishing removal rate of a metallic material during polishing of an object to be polished containing a resin material and a metallic material, and the polishing removal rate of a resin material relative to the polishing removal rate of a metallic material (i.e., the ratio of the polishing removal rate of a resin material to the polishing removal rate of a metallic material) (hereinafter referred to as “metal/resin polishing removal rate ratio”) is preferably 0.4 or more and 2.0 or less. The reason why the metal/resin polishing removal rate ratio is preferably 0.4 or more and 2.0 or less is because a metal and a resin can be polished at the same level and therefore an object to be polished can have a flat surface after polishing. In the surface of an object to be polished, both a layer made of a metallic material (metallic layer) and a layer made of a resin material (resin layer) are present, and such an object to be polished containing these two different materials in its surface is to be polished. Here, when the metal/resin polishing removal rate ratio is 0.4 or more and 2.0 or less, both the metallic layer and the resin layer can be processed at the same time. The metal/resin polishing removal rate ratio is preferably 0.5 or more, more preferably 0.6 or more, even more preferably 0.7 or more, particularly preferably 0.8 or more, most preferably 0.9 or more. The metal/resin polishing removal rate ratio is preferably 1.8 or less, more preferably 1.6 or less, even more preferably 1.5 or less, particularly preferably 1.3 or less, most preferably 1.2 or less.

Therefore, the polishing composition is preferably designed so as to achieve a metal/resin polishing removal rate ratio of 0.4 or more and 2.0 or less. At this time, the metal/resin polishing removal rate ratio is preferably 0.5 or more and 1.8 or less, more preferably 0.6 or more and 1.6 or less, even more preferably 0.7 or more and 1.5 or less, particularly preferably 0.8 or more and 1.3 or less, most preferably 0.9 or more and 1.2 or less.

### [Method for Producing Polishing Composition]

A method for producing the first polishing composition (preparation method) is not limited. For example, a production method may appropriately be used which includes mixing abrasives, a first amine compound, a second amine compound, a dispersion medium (preferably water), and another optional component with stirring. It should be noted that the abrasives, the first amine compound, the second amine compound, the dispersion medium, and the another component are the same as those described above in the section <Polishing composition>, and therefore the description thereof is not repeated here.

A method for producing the second polishing composition (preparation method) is not limited. For example, a production method may appropriately be used which includes mixing abrasives, a second amine compound, a dispersion medium (preferably water), and another optional component with stirring. It should be noted that the abrasives, the second amine compound, the dispersion medium, and the another component are the same as those described above in the section <Polishing composition>, and therefore the description thereof is not repeated here.

In production of the first polishing composition and the second polishing composition, the temperature at which the respective components are mixed is not limited but is preferably 10 °C or higher and 40 °C or lower, and heating may be performed to increase the rate of dissolution. Further, a mixing time is not limited, either.

### <Polishing Method>

Another aspect of the present invention relates to a polishing method including the step of polishing an object to be polished containing a resin material and a metallic material by use of the polishing composition described above. A preferred example of the object to be polished according to the present aspect is the same as that described above in [Object to be polished].

When the object to be polished is polished using the polishing composition, an apparatus and conditions usually used for polishing can be used. Examples of a general polishing apparatus include a single-side polishing apparatus and a double-side polishing apparatus. The single-side polishing apparatus is generally used in the following manner: an object to be polished is held using a holding tool called “carrier”, and a platen having a polishing pad attached thereto is pressed against one of the surfaces of the object to be polished and is rotated while a polishing composition is supplied from above to polish the one surface of the object to be polished. The double-side polishing apparatus is generally used in the following manner: an object to be polished is held using a holding tool called “carrier”, platens each having a polishing pad attached thereto are pressed against facing surfaces of the object to be polished and are rotated in opposite directions while a polishing composition is supplied from above to polish both surfaces of the object to be polished. At this time, the object to be polished is polished by a physical action caused by friction between the polishing pad and the polishing composition and the object to be polished and a chemical action caused by the polishing composition on the object to be polished. The polishing pad is not limited, and any porous body such as nonwoven cloth, polyurethane, or swede can be used. The polishing pad is preferably processed to be able to hold a polishing liquid.

Examples of the polishing conditions include polishing pressure, platen rotational speed, carrier rotational speed, flow rate of polishing composition, and polishing time. These polishing conditions are not limited. For example, the polishing pressure is preferably 0.1 psi (0.69 kPa) or more and 10 psi (69 kPa) or less, more preferably 0.5 psi (3.5 kPa) or more and 8.0 psi (55 kPa) or less, even more preferably 1.0 psi (6.9 kPa) or more and 6.0 psi (41 kPa) or less per unit area of the object to be polished. Generally, a frictional force exerted by the abrasives increases as the pressure increases so that a polishing removal rate increases because of an increase in mechanical processing force. When the polishing pressure is within the above range, an adequate polishing removal rate is achieved, and it is possible to prevent the breakage of the object to be polished caused by the pressure and the occurrence of a surface defect such as a scratch. The platen rotational speed and the carrier rotational speed are preferably 10 rpm (0.17 s⁻¹) or more and 500 rpm (8.3 s⁻¹) or less. The amount (flow rate) of the polishing composition to be supplied is not limited as long as the object to be polished is entirely covered with the polishing composition, and may be adjusted depending on conditions such as the size of the object to be polished etc. A method for supplying the polishing composition to the polishing pad is not limited, either, and may be, for example, a method in which the polishing composition is continuously supplied with a pump or the like. The processing time is not limited as long as a desired processing result is obtained, but is preferably short due to a high polishing removal rate.

A still another aspect of the present invention relates to a method for producing a polished object, including the step of polishing an object to be polished by the polishing method described above. A preferred example of the object to be polished according to the present aspect is the same as that described above in [Object to be polished]. A preferred example of the method is a method for producing an electronic circuit board, including polishing an object to be polished containing a resin material and a metallic material.

Although the embodiments of the present invention have been described in detail, this is illustrative and exemplary and not restrictive, and it is clear that the scope of the present invention should be interpreted by the appended claims.

The present invention encompasses the following aspects and embodiments.
[1] A polishing composition to be used for polishing an object to be polished containing a resin material and a metallic material, the polishing composition containing abrasives, a first amine compound having 0 or 1 amino group (—NH₂), a second amine compound having two or more amino groups (—NH₂), and a dispersion medium.
[2] A polishing composition to be used for polishing an object to be polished containing a resin material and a metallic material, the polishing composition containing abrasives, a second amine compound having 2 or more amino groups (—NH₂), and a dispersion medium.
[3] The polishing composition according to the above [1], wherein the first amine compound is an amino alcohol having 1 or more and 6 or less carbon atoms, and the second amine compound is an aliphatic amine compound having 1 or more and 6 or less carbon atoms.
[4] The polishing composition according to the above [2], wherein the second amine compound is an aliphatic amine compound having 1 or more and 6 or less carbon atoms.
[5] The polishing composition according to the above [1] or [3], wherein the first amine compound contains at least one selected from the group consisting of 2-aminoethanol, 1-amino-2-propanol, aminoethylpiperazine, triethanolamine, and 2-(2-aminoethylamino) ethanol, or the second amine compound contains at least one selected from the group consisting of ethylenediamine, diethylenetriamine, 1,2-diamino-2-methylpropane, 1,4-cyclohexanediamine, 1,3-propanediamine, or 1,2-propanediamine.
[6] The polishing composition according to the above [2] or [4], wherein the second amine compound contains at least one selected from the group consisting of ethylenediamine, diethylenetriamine, 1,2-diamino-2-methylpropane, 1,4-cyclohexanediamine, 1,3-propanediamine, or 1,2-propanediamine.
[7] The polishing composition according to any one of the above [1] to [6], wherein a polishing removal rate ratio of the resin material to the metallic material (polishing removal rate of resin material/polishing removal rate of metallic material) is 0.4 or more and 2.0 or less.
[8] A polishing method including polishing an object to be polished containing a resin material and a metallic material by use of the polishing composition according to any one of the above [1] to [7].

### EXAMPLES

Examples of the present invention will be described. However, the technical scope of the present invention is not limited only to the following examples. It should be noted that unless otherwise specified, “%” and “part(s)” respectively mean “% by mass” and “part(s) by mass”.

### EXAMPLES

### Preparation of Polishing Compositions of Examples 1 to 10 and Comparative Examples 1 to 7

Alumina particles (volume average secondary particle size (D₅₀): 0.3 μm) as abrasives, one selected from the group consisting of 2-aminoethanol, 1-amino-2-propanol, aminoethylpiperazine, triethanolamine, or 2-(2-aminoethylamino) ethanol as a first amine compound, one selected from the group consisting of ethylenediamine, diethylenetriamine, 1,2-diamino-2-methylpropane, 1,4-cyclohexanediamine, 1,3-propanediamine, or 1,2-propanediamine as a second amine compound, and water as a dispersion medium were mixed with stirring to prepare a polishing composition whose the value of pH was adjusted to 11.5 with potassium hydroxide (mixing temperature: about 25 °C, mixing time: about 30 minutes). It should be noted that the compounds as a first amine compound and a second amine compound were selected to achieve a composition shown in Table 1. Specifically, the polishing compositions of Examples 1 to 4 used, as an amine compound, the first amine compound and the second amine compound (mass ratio of first amine compound:second amine compound=1:1), the polishing compositions of Examples 5 to 10 used, as an amine compound, only the second amine compound (in this case, the second amine compound is also referred to as “third amine compound”), the polishing composition of Comparative Example 1 did not use an amine compound, and the polishing compositions of Comparative Examples 2 to 7 used, as an amine compound, only the first amine compound.

In this way, polishing compositions of Examples 1 to 10 and Comparative Examples 2 to 7 having an abrasive concentration of 4.0% by mass and an amine compound concentration of 10.0% by mass were prepared. It should be noted that when the first amine compound and the second amine compound were contained, the amine compound concentration was the total concentration of them, and the first amine compound and the second amine compound were used in a mass ratio of 1:1.

When the polishing composition was evaluated for polishing removal rate, a polishing removal rate test was performed in which the polishing composition was further mixed with 31 mass % hydrogen peroxide in an amount of 30 cc (30 ml) per liter of the polishing composition.

Each of the polishing compositions obtained above was evaluated for polishing removal rate and resin/metal polishing removal rate ratio (PI/Cu polishing removal rate ratio) in accordance with a method that will be described below in [Polishing removal rate].

### Evaluation

### [Average Particle Size (D₅₀) of Alumina Particles]

The volume-based particle size distribution of the alumina particles used as abrasives was determined by measurement using particle size distribution measuring equipment (Microtrac particle size distribution measuring equipment MT 3300EX II manufactured by Microtrac BEL). A particle size when a cumulative volume percentage from a small particle size side in the obtained particle size distribution reached 50% was defined as an average particle size (D₅₀) of the alumina particles.

### [Polishing Removal Rate]

As objects to be polished, a polyimide (PI) substrate and a copper (Cu) substrate were prepared. Then, these objects to be polished were polished using each of the polishing compositions and a polishing apparatus described below under polishing conditions described below, and the polishing removal rate of each of the objects to be polished was evaluated in accordance with a method (polishing removal rate evaluation method) described below.

### (Object to be Polished)

Polyimide substrate . . . Size: 30 mm×30 mm (manufactured by Asahi Kasei Corp., trade name: PIMEL BM302H)
Copper substrate . . . Size: 45 mm×45 mm, rolled oxygen-free copper

### (Polishing Apparatus and Polishing Conditions)

Polishing apparatus: Small desktop polishing machine (manufactured by Engis Japan Corporation, EJ380 IN) platen diameter: 380 [mm]
Polishing pad: Non-woven cloth pad (manufactured by NITTA Dupont Incorporated, SUBA800)
Platen rotational speed: 340 [rpm]
Head (carrier) rotational speed: 50 [rpm]
Polishing pressure: 3.0 [psi] (210 [g/cm²], 207 kPa)
Flow rate of polishing composition: 80 [mL/min]
Polishing time: 1 [min]

### (Polishing Removal Rate Evaluation Method)

1. The mass of an object to be polished was measured using an analytical balance XS205 (manufactured by Mettler Toledo) before and after polishing, and a difference between the measured masses was calculated as the amount of mass change ΔM [kg] of the object to be polished before and after polishing.
2. The amount of mass change ΔM [kg] of the object to be polished before and after polishing was divided by the specific gravity of the object to be polished (the specific gravity of a material to be polished) to calculate the amount of volume change ΔV [m³] of the object to be polished before and after polishing.
3. The amount of volume change ΔV [m³] of the object to be polished before and after polishing was divided by the area S [m²] of polished surface of the object to be polished to calculate the amount of thickness change Δd [m] of the object to be polished before and after polishing.
4. The amount of thickness change Δd [m] of the object to be polished before and after polishing was divided by the polishing time t [min], and the unit was further converted to [μm/min]. The thus obtained value was defined as a polishing removal rate v [μm/min].

The evaluation results are shown below in Table 1. It should be noted that “-” in Table 1 shown below means that the component was not used.

TABLE 1

| | | | | Second amine compound | | | | | |
|---|---|---|---|---|---|---|---|---|---|
| | First amine compound | | | (Third amine compound) | | | Polishing | | Polishing |
| | | Number | | | Number | | removal | | removal |
| | | of R- | Number | | of R- | Number | rate | | rate |
| | | NH₂ | of N | | NH₂ | of N | (μm/min) | | ratio |
| | Compound | groups | atoms | Compound | groups | atoms | PI | Cu | PI/Cu |
| Example 1 | 1-Amino-2-propanol | 1 | 1 | Diethylenetriamine | 2 | 3 | 5.2 | 4.8 | 1.1 |
| Example 2 | 1-Amino-2-propanol | 1 | 1 | Ethylenediamine | 2 | 2 | 4.7 | 4.8 | 1.0 |
| Example 3 | 2-Aminoethanol | 1 | 1 | 1,2-Diamino-2-methylpropane | 2 | 2 | 4.8 | 4.9 | 1.0 |
| Example 4 | 2-Aminoethanol | 1 | 1 | 1,4-Cyclohexanediamine | 2 | 2 | 5.2 | 4.2 | 1.2 |
| Example 5 | — | — | — | Ethylenediamine | 2 | 2 | 5.1 | 10.2 | 0.5 |
| Example 6 | — | — | — | Diethylenetriamine | 2 | 3 | 4.3 | 8.3 | 0.5 |
| Example 7 | — | — | — | 1,4-Cyclohexanediamine | 2 | 2 | 4.4 | 7.5 | 0.6 |
| Example 8 | — | — | — | 1,2-Diamino-2-methylpropane | 2 | 2 | 4.5 | 9.8 | 0.5 |
| Example 9 | — | — | — | 1,2-Propanediamine | 2 | 2 | 5.0 | 5.1 | 1.0 |
| Example 10 | — | — | — | 1,3-Propanediamine | 2 | 2 | 5.4 | 3.7 | 1.5 |
| Comparative | — | — | — | — | — | — | 1.9 | 0.3 | 6 |
| Example 1 | | | | | | | | | |
| Comparative | Triethanolamine | 0 | 1 | — | — | — | 4.0 | 0.3 | 12 |
| Example 2 | | | | | | | | | |
| Comparative | 2-Aminoethanol | 1 | 1 | — | — | — | 4.5 | 1.1 | 4 |
| Example 3 | | | | | | | | | |
| Comparative | 1-Amino-2-propanol | 1 | 1 | — | — | — | 5.0 | 0.7 | 7 |
| Example 4 | | | | | | | | | |
| Comparative | Aminoethylpiperazine | 1 | 3 | — | — | — | 3.7 | 0.4 | 9 |
| Example 5 | | | | | | | | | |
| Comparative | 2-(2-Aminoethylamino)ethanol | 1 | 2 | — | — | — | 4.2 | 1.7 | 2.5 |
| Example 6 | | | | | | | | | |
| Comparative | 2-Aminoethanol | 1 | 1 | — | — | — | 4.7 | 0.9 | 5.1 |
| Example 7 | 1-Amino-2-propanol | 1 | 1 | | | | | | |

When each of the polishing compositions of Examples was used, the polishing removal rate of polyimide and the polishing removal rate of copper were maintained at high level. Further, the polishing compositions of Examples allowed the ratio of the polishing removal rate of polyimide to the polishing removal rate of copper (PI/Cu polishing removal rate ratio) to fall within a range of 0.4 or more and 2.0 or less, that is, the polishing removal rate of polyimide and the polishing removal rate of copper were at about the same level, and therefore an appropriate balance was achieved between them. This confirmed that the use of the polishing composition according to the present aspect made it possible to appropriately adjust the ratio of the polishing removal rate of polyimide to the polishing removal rate of copper (PI/Cu polishing removal rate ratio) while maintaining the polishing removal rates at high level. On the other hand, when each of the polishing composition of Comparative Example 1 containing no amine compounds and the polishing compositions of Comparative Examples 2 to 7 containing only the first amine compound as an amine compound was used, the polishing removal rate of polyimide and the polishing removal rate of copper were low and inadequate, and the ratio of the polishing removal rate of polyimide to the polishing removal rate of copper (PI/Cu polishing removal rate ratio) was high and excessive. This confirmed that the polishing composition containing no amine compounds (first amine compound and second amine compound) and the polishing composition containing only the first amine compound as an amine compound could not adjust the ratio of the polishing removal rate of polyimide to the polishing removal rate of copper (PI/Cu polishing removal rate ratio).

This application is based on Japanese Patent Application No. 2023-83318 filed on May 19, 2023 and Japanese Patent Application No. 2023-103624 filed on Jun. 23, 2023, the disclosures of which are incorporated herein by reference in their entirety.

1-8. (canceled)

9. A polishing composition to be used for polishing an object to be polished containing a resin material and a metallic material, the polishing composition comprising:
abrasives:
a first amine compound having 0 or 1 amino group (—NH₂);
a second amine compound having two or more amino groups (—NH₂); and
a dispersion medium.

10. A polishing composition to be used for polishing an object to be polished containing a resin material and a metallic material, the polishing composition comprising:
abrasives;
a second amine compound having two or more amino groups (—NH₂); and
a dispersion medium.

11. The polishing composition according to claim 9,
wherein the first amine compound is an amino alcohol having 1 or more and 6 or less carbon atoms, and
the second amine compound is an aliphatic amine compound having 1 or more and 6 or less carbon atoms.

12. The polishing composition according to claim 10, wherein the second amine compound is an aliphatic amine compound having 1 or more and 6 or less carbon atoms.

13. The polishing composition according to claim 9,
wherein the first amine compound comprises at least one selected from the group consisting of 2-aminoethanol, 1-amino-2-propanol, aminoethylpiperazine, triethanolamine, or 2-(2-aminoethylamino) ethanol, and
the second amine compound comprises at least one selected from the group consisting of ethylenediamine, diethylenetriamine, 1,2-diamino-2-methylpropane, 1,4-cyclohexanediamine, 1,3-propanediamine, or 1,2-propanediamine.

14. The polishing composition according to claim 10, wherein the second amine compound comprises at least one selected from the group consisting of ethylenediamine, diethylenetriamine, 1,2-diamino-2-methylpropane, 1,4-cyclohexanediamine, 1,3-propanediamine, and 1,2-propanediamine.

15. The polishing composition according to claim 9, wherein a polishing removal rate ratio of the resin material to the metallic material (polishing removal rate of resin material/polishing removal rate of metallic material) is 0.4 or more and 2.0 or less.

16. A polishing method comprising polishing an object to be polished containing a resin material and a metallic material by use of the polishing composition according to claim 9.

17. The polishing composition according to claim 10, wherein a polishing removal rate ratio of the resin material to the metallic material (polishing removal rate of resin material/polishing removal rate of metallic material) is 0.4 or more and 2.0 or less.

18. A polishing method comprising polishing an object to be polished containing a resin material and a metallic material by use of the polishing composition according to claim 10.
